(19) United States
(12) Patent Application Publication
(10) Pub. No.: US 2011/0064233 A1
(43) Pub. Date: Mar. 17, 2011

(54) Method, apparatus and system for synthesizing an audio performance using Convolution at Multiple Sample Rates

(76) Inventor: James Edwin Van Buskirk, Cedar Park, TX (US)

(21) Appl. No.: 10/575,278

(22) PCT Filed: Oct. 8, 2004
(86) PCT No.: PCT/US04/33290

§ 371 Date: Mar. 5, 2007

Related U.S. Application Data
(60) Provisional application No. 60/510,019, filed on Oct. 9, 2003.
(60) Provisional application No. 60/510,068, filed on Oct. 9, 2003.

(51) Int. Cl. H03G 3/00

(52) U.S. Cl. 381/61

(57) ABSTRACT

A method, apparatus, and system (48) are disclosed for use in synthesizing an audio performance (50) in which one or more acoustic characteristics, such as acoustic space, microphone modeling and placement, can selectively be varied. In order to reduce processing time, the system utilizes pseudo-convolution processing techniques (54) at a greatly reduced processor load. The system is able to emulate the audio output in different acoustic spaces, separate musical sources (instruments and other sound sources) from musical context; interactively recombine (56) musical source and musical context with relatively accurate acoustical integrity, including surround sound contexts, emulate microphone models and microphone placement, create acoustic effects, such as reverberation (58), emulate instrument body resonance and interactively switch emulated instrument bodies on a given musical instrument.

### CROSS REFERENCE TO RELATED APPLICATIONS

This application claims the benefit of U.S. provisional patent application Nos. 60/510,068 and 60/510,019, both filed on Oct. 9, 2003.

### BACKGROUND OF THE INVENTION

### COMPUTER LISTING APPENDIX

This application includes a Computer Listing Appendix on compact disc, hereby incorporated by reference.

1. Field of the Invention

The present invention relates generally to audio processing and, more particularly, to a method, apparatus, and system for synthesizing an audio performance in which one or more acoustic characteristics, such as acoustic space, microphone modeling and placement, are varied using pseudo-convolation processing techniques.

2. Description of the Prior Art

Digital music synthesizers are known in the art. An example of such a digital music synthesizer is disclosed in U.S. Pat. No. 5,502,747, hereby incorporated by reference. The system disclosed in the '747 patent discloses multiple component filters and is based on hybrid time domain and frequency domain processing. Unfortunately, the methodology utilized in the U.S. Pat. No. 5,502,747 patent is relatively computationally intensive and is thus not efficient. As such, the system disclosed in the '747 patent is primarily only useful in academic and scientific applications where computation time is not critical. Thus, there is a need for an efficient synthesizer that is relatively more efficient than those in the prior art.

### SUMMARY OF THE INVENTION

The present invention relates to a method, apparatus, and system for use in synthesizing an audio performance in which one or more acoustic characteristics, such as acoustic space, microphone modeling and placement, can selectively be varied. In order to reduce processing time, the system utilizes pseudo-convolution processing techniques at a greatly reduced processor load. The system is able to emulate the audio output in different acoustic spaces, separate musical sources (instruments and other sound sources) from musical context; interactively recombine musical source and musical context with relatively accurate acoustical integrity, including surround sound contexts, emulate microphone models and microphone placement, create acoustic effects, such as reverberation, emulate instrument body resonance and interactively switch emulated instrument bodies on a given musical instrument.

### BRIEF DESCRIPTION OF THE DRAWING

FIGS. 1A and 1B are exemplary graphical user interfaces for use with the present invention.

FIGS. 1C and 1D are alternate exemplary graphical user interfaces for use with the present invention.

FIG. 2 is a high level block diagram of one embodiment of the present invention;

FIG. 3 is a block diagram of an exemplary embodiment of a run-time input channel processing routine designated by the block 50 in FIG. 2 in accordance with the present invention;

FIG. 4 is a more detailed block diagram of the embodiment illustrated in FIG. 2;

FIG. 5 is a block diagram illustrating a process channel routine designated by the block 53 in FIG. 2 in accordance with the present invention;

FIG. 6 is a time domain response of an exemplary sound impulse;

FIG. 7 is a block diagram of an audio collection and index sequencing routine illustrated by the block 178 in FIG. 5 in accordance with the present invention, represented by the blocks 178a, 178b and 178c-, which illustrate different operational modes for the Audio Collection and Index Servicing Routine in accordance with the the present invention.

FIG. 8 is a block diagram of coefficient index sequencing routine illustrated by the block 170 in FIG. 5 in accordance with the present invention; and

FIG. 9 is a block diagram of the collection index modulo update routine illustrated by the block 192 in FIG. 7 in accordance with the present invention.

FIG. 10 is a block diagram of the frame modulo update in accordance with the present invention;

FIG. 11 is an exemplary block diagram of the tail extension processing in accordance with the present invention;

FIG. 12 is a hardware block diagram of a computing platform for use with the present invention.

### DETAILED DESCRIPTION

The present invention relates to an audio processing system for synthesizing an acoustic response in which one or more acoustic characteristics are selectably varied. For example, the audio response in a selectable musical context or acoustical space can be emulated. In particular, a model of virtually any acoustic space, for example, Carnegie Hall, can be recorded and stored. In accordance with one aspect of the invention, the system emulates the acoustic response in the selected acoustic space model, such that the audio input sounds as if it were played in Carnegie Hall, for example.

In accordance with one aspect of the invention, the system has the ability to separate musical sources (i.e. instruments and other sound sources) from the musical context (i.e. acoustic space in which the sound sources are played). By emulating the response to selectable music contexts, as described above, the acoustic response to various musical sources can be emulated for virtually any acoustic space: including the back seat of a station wagon.

Various techniques can be used for generating a model of an acoustic space. The model may be considered a fingerprint of a room or other space or musical context. The model is created, for example, by recording the room response to a sound impulse, such as a shot from a starter pistol or other acoustic input. The sound impulse may be created, for example, by placing a speaker in the room or space to be modeled and playing a frequency sweep. More particularly, a common technique is the sine sweep method which has a sweep tone and a complementary decode tone. The convolution of the sweep tone and the decode tone is a perfect single sample spike (impulse). After the sweep tone is played through the speaker and recorded by a microphone in the room, the resulting recording is convolved with the decode tone which reveals the room impulse response. Alternatively, simply firing a starter pistol in the space and recording the response is another way. Alternatively, various “canned” acoustic space models are currently available on the Internet at http:/www.echochamber.ch[!]; http:/altiverb.claw-mac.com; and http:/noisevault.com.

In accordance with other aspects of the invention, the system is able to emulate other acoustic characteristics, such as the response to one or more predetermined microphones, such as a vintage AKG C-12 microphone. The microphone is emulated in the same manner as the musical context. In particular, the acoustic response to an acoustic impulse of the vintage microphone, for example, is recorded and stored. Any musical source played through the system is processed so that it sounds as if it were played through the vintage microphone.

The system is also able to emulate other acoustic characteristics, such as the location of an audio source within an audio context. In particular, in accordance with another aspect of the invention, the system is able to combine a sound source, the response of an acoustic space, a microphone and an instrument body resonance response into separate, reconfigurable audio sources in an audio performance. For example, when an instrument, say a violin, is performed in a room and recorded through a microphone, the resulting audio contains tonality and reverberation dictated by multiple impulse elements, namely the microphone, room acoustics and the violin body. In many cases it is desirable to control these three elements individually and separate from each other and the string vibration of the violin. By doing so, different choices of microphone, room environment or violin body can be independently selected by the user or content author for an audio performance. In addition, the system is able to optionally emulate the response to another audio characteristic, such as the location of an audio source relative to the microphone placement, thus allowing the audio source to be virtually moved relative to the microphone. As such, drums, for example, can be made to sound closer or further apart from the microphones.

In accordance with another aspect of the invention, the system is a real time audio processing system that is significantly less computation intensive than known music synthesizers, such as the audio processing system disclosed in the '747 patent discussed above. In particular, various techniques are used to reduce the processing load relative to known systems. For example, as will be described in more detail below, in a “Turbo” mode of operation, the system processes input audio samples at a slower sample rate than the input sample rate thus reducing the processor load up to 75%, for example.

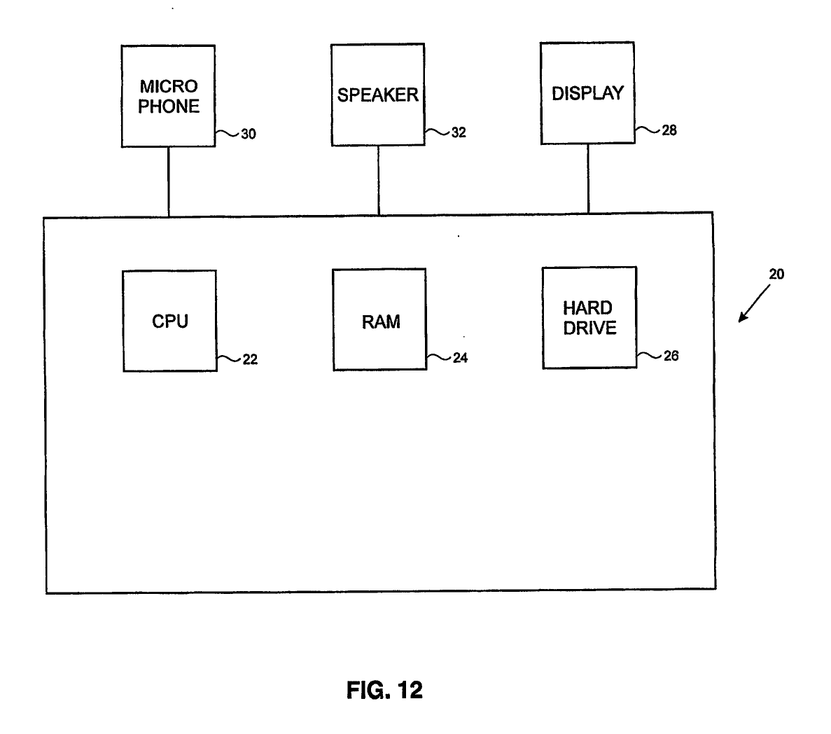

An exemplary host computing platform for use with the present invention is illustrated in FIG. 12 and generally identified with the reference numeral 20. The host computing platform when loaded with the user interface and processing algorithm described below forms an audio synthesizer. The host computing platform 20 includes a CPU 22, a random access memory (RAM) 24, a hard drive 26, as well as an external display 28, an external microphone 30 and one or more external speakers 32. Minimum requirements for the host computing platform 20 are: Windows XP (Pro, Home edition, embedded or other compatible operating system), an Intel Pentium 4, Celeron, Athlon XP 1 GHz or other CPU, 256 MB RAM, 20 GB hard drive.

### User Interface

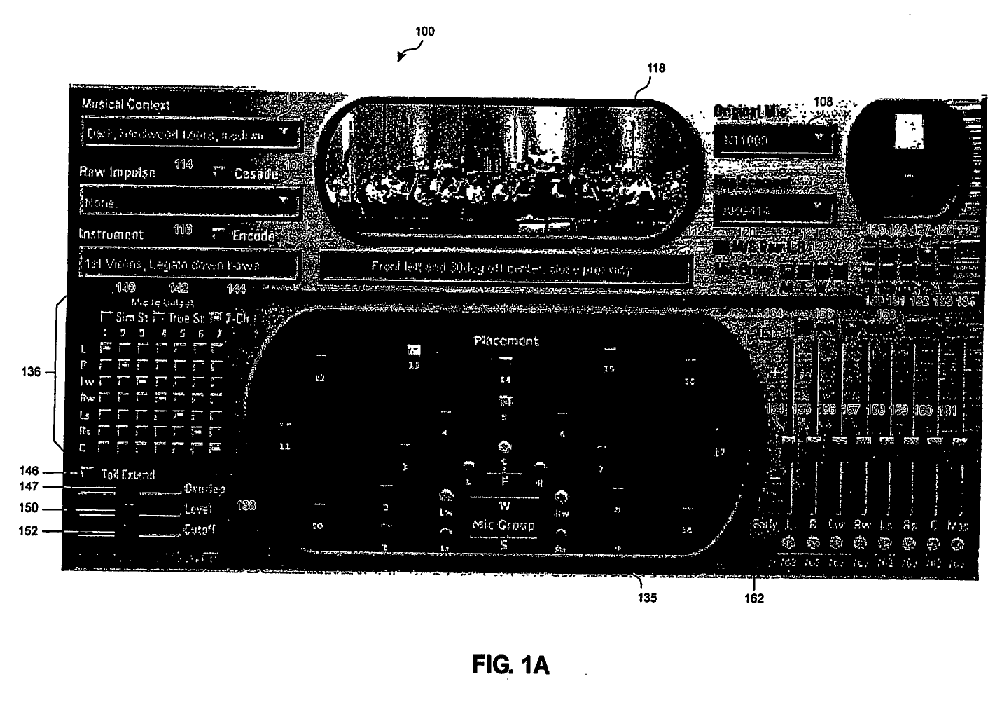

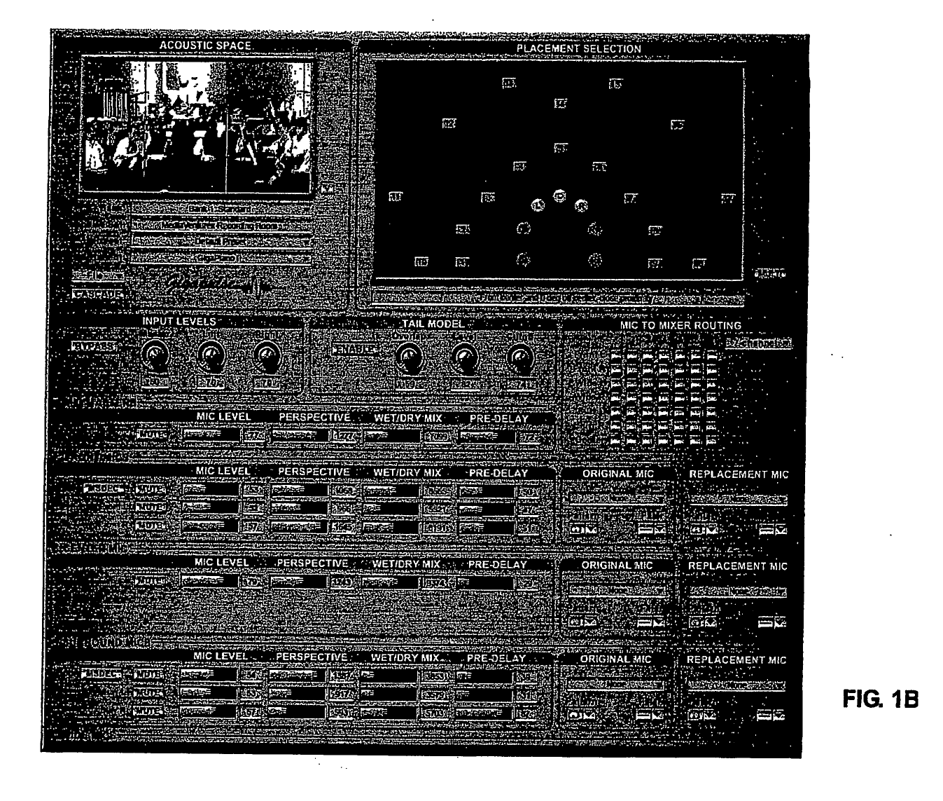

FIGS. 1A-1D illustrate graphical representations of exemplary embodiments of a control panel 100 which may be used in connection with the present invention. Only one embodiment is described for simplicity. In particular, in the embodiment illustrated in FIG. 1A, the control panel 100 includes a drop-clown menu 102 which may be used to select a predetermined musical context (e.g., dark, hardwood floors, medium . . . ), a drop-down menu 104 which may be used to select a “raw impulse”, a drop-down menu 106 which may be used to select a particular musical instrument (e.g., 1^{st} violins, Legato down bows), a drop-down menu 108 which may be used to select an original microphone (e.g., NT1000), and a drop-down menu 110 which may be used to select a particular replacement microphone (e.g., AKG414). A display area 112 is provided for displaying a brief textual description of a microphone placement selection, as described in more detail below.

A button 114 is provided for selectively enabling and disabling a “cascade” feature associated with application of the raw impulse selected via the drop-down menu 104 to an audio track. A button 116 is provided for selectively enabling and disabling an “encode” feature which permits the application of a user-selected acoustic model to the instrument selected via the drop-down menu 106. A display area 118 optionally may show a graphical or photographic representation of the musical context selected by the drop-down menu 102.

A button 120 is provided for selectively activating and deactivating a mid/side (M/S) microphone pair arrangement for left-side and right-side microphones. Additional buttons 121, 122, 123, and 124 are provided for specifying groups of microphones, including, for example, all microphones (button 121), from (“F”) microphones (button 122), wide (“W”) microphones (button 123), and rear or surround (“S”) microphones (button 124).

The user also may enter microphone polar patterns and roll-off characteristics for each of the microphones employed in any given simulation. For that purpose, buttons 124, 125, 126, 127, 128, and 129 are provided for selecting a microphone roll-off characteristic or response. For example, buttons 125 and 126 select two different low-frequency bumps; button 127 selects a flat response, and buttons 128 and 129 select two different low-frequency roll-off responses, respectively. Similarly, buttons 130-134 allow a user to select one of several different well-recognized microphone polar patterns, such as an omni-directional pattern (button 130), a wide-angle cardioid pattern (button 131), a cardioid pattern (button 132), a hyper cardioid pattern (button 133), or a so-called “figure-8” pattern (button 134).

The control panel 100 also includes a placement control section 135, which, in the illustrated embodiment, contains a plurality of placement selector/indicator buttons (designated by numbers 1 through 18). These placement selector/indicator buttons allow a user to specify a position of musical instruments within the user-selected musical context (e.g., the position of the instrument selected by the drop-down menu 106 relative to the user-specified microphone(s)). The graphical display area 118 may display a depiction of the perspective of the room or musical context selected by the drop-down menu 102 corresponding to the placement within that room or musical context specified by the particular placement selector/indicator button actuated by the user. Of course, as will be readily apparent to those of ordinary skill in the art, many different alternative means may be employed to permit a user to select instrument placements within a particular musical context in addition to or instead of the placement selector/indicator buttons shown in FIG. 1A. For example, a graphical depiction of the room or musical context could be displayed, and a mouse, trackball, or other conventional pointer control device could be used to move a location designator to a predetermined placement within the graphical depiction of the room or musical context corresponding to whatever placement within that room or musical context may be desired by the user.

As also shown in FIG. 1A, the control panel 100 also includes a “mic-to-output” control section 136, which includes an array of buttons allowing a user to assign each microphone used in a given simulation to a corresponding mixer output channel. As shown, the control panel 100 provides for seven mixer output channels represented by the columns of buttons numbered one through seven in the mic-to-output control section 136. Seven mixer output channels allow for seven microphones to be used in a given simulation (e.g., left and right front, left and right wide, left and right surround, and a center channel). Of course, those of ordinary skill in the art will readily appreciate that more or fewer mixer output channels may be provided in any given embodiment of the present invention based upon the needs of a particular simulator. For example, in a stereo simulator, only two mixer output channels need be provided. In order to assign a particular microphone to a particular mixer output channel, the user need only depress the button in the row of buttons corresponding to the particular microphone and the column of buttons corresponding to the particular mixer output channel. The controls in each row of the mic-to-output control section 136 operate in a mutually exclusive fashion, such that a particular microphone can be associated only with one mixer output channel at a time.

The mic-to-output control section 136 also includes a button 140 for selectively enabling and disabling a “simulated stereo” mode in which a single microphone simulation or output is processed to develop two (i.e., stereo) mixer output channels. This may be used, for example, to enable a simulated stereo output to be produced by a slow computer which does not have sufficient processing power to handle full stereo real-time processing. A button 142 is provided for selectively enabling a “true stereo” mode, which simply couples left and right stereo microphone simulations or outputs to two mixer output channels. Further, a button 144 is provided for selectively enabling and disabling a “seven-channel” mode in which each of seven microphone simulations or outputs is coupled to a respective mixer output channel to provide for full seven-channel surround sound output.

A button 146 is provided for selectively enabling and disabling a “tail extend” feature which causes the illustrated synthesizer to derive the first N seconds of the synthesized response by performing a full convolution and then to derive an approximation of the tail or terminal portion of the synthesized response using a recursive algorithm (described in mare detail below) which is lossy but computationally efficient. Where exact acoustically simulation is not required, enabling the tail extend feature provides a trade-off between exact acoustical simulation and computational overhead. Associated with the tail extend feature are three parameters, Overlap, Level, and Cutoff, and a respective slider control 148, 150, and 152 is provided for adjustment of each of these parameters.

More particularly, the slider control 148 permits adjustment of an amount of overlap between the recursively generated tail portion of the synthesized response or output signal and a time-wise prior portion of the output signal which is calculated by convolution at a particular sample rate. The slider control 150 permits adjustment of the level of the recursively generated portion of the output signal so that it more closely matches the level of the time-wise prior convolved portion of the output signal. The slider control 152 permits adjustment of the frequency-domain cutoff between the recursively generated portion of the output signal and the time-wise prior convolved portion thereof to thereby smooth the overall spectral damping of the synthesized response or output signal such that the frequency-domain bandwidth of the recursively generated portion of the output signal more closely matches the frequency domain bandwidth of the convolved portion thereof at the transition point between those two portions.

A plurality of further slider controls may be provided to allow a user to adjust the level corresponding to each microphone used in a particular simulation. In the illustrated embodiment, slider controls 154-160 are provided for adjusting recording levels of each of seven recording channels, each corresponding to one of the available microphones in the illustrated simulation or synthesizer system. In addition, a master slider control 161 is provided to allow a user to simultaneously adjust the levels set by each of the slider controls 154-160. As shown, a digital read-out is provided in tandem with each slider control 154-161 to indicate numerically to the user the level set at any given time by the corresponding slider control 154-161. In the illustrated embodiment, the levels are represented by 11-bit numbers ranging from 0 to 2047. However, it should be evident to those of ordinary skill in the art that any other suitable range of levels in any suitable units could be used instead.

The control panel 100 also includes a level button 164, a perspective button 166, and a pre-delay button 168. The level button 164 allows a user to selectively activate and deactivate the level controls 154-161. The perspective button 166 allows the user to selectively activate and deactivate a perspective feature which allows the slider controls 154-161 to be used to adjust a parameter which simulates, for any given simulation, varying the physical dimensions of the musical context or room selected by the drop-down menu 102. The pre-delay button 168 allows the user to employ the slider controls 154-161 to adjust a parameter which simulates echo response speed (by adjusting the simulated lag between the initial echo in a recorded signal and a predetermined amount of echo density buildup).

Alternate exemplary graphical user interfaces (GUI) are illustrated in FIGS. 1B-1D. These GUIs also permit a user to adjust the various parameters of the system in accordance with the principles of the present invention. Since the GUI provides essentially the same functionality as the control panel illustrated in FIG. 1A, the alternate GUIs are not described further.

### Processing Algorithm

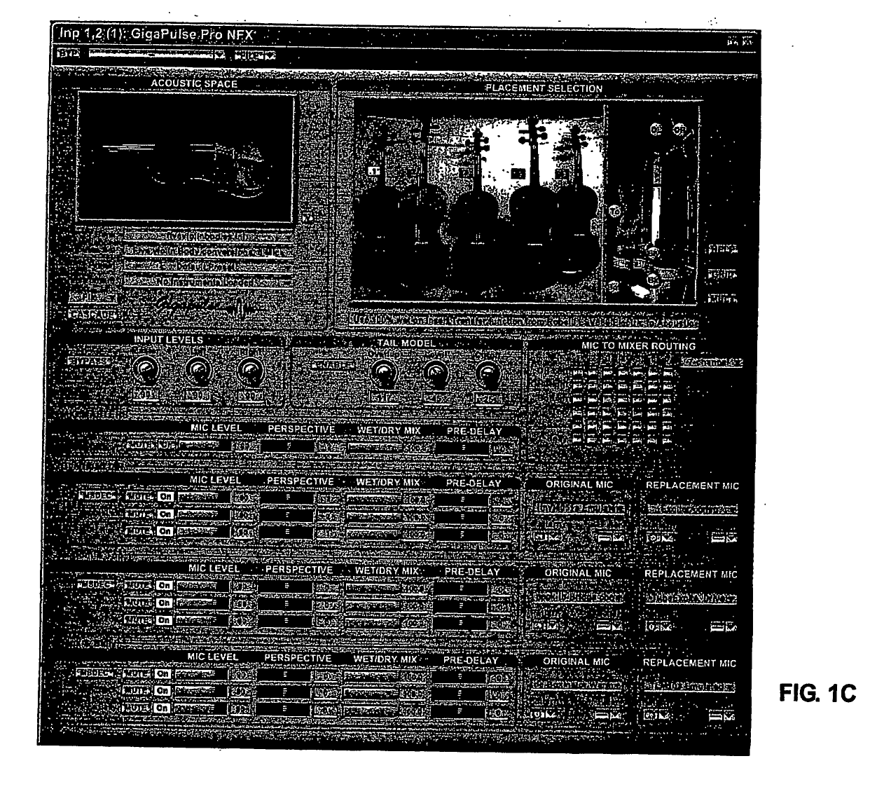

FIG. 2 depicts a high-level software block diagram, illustrating a single audio channel for simplicity, of an exemplary embodiment of an audio processing system 48 in accordance with the present invention. The audio processing system 48 includes a runtime input channel processing routine 50, a runtime sequencing, control, and data manager 52, a process-channel module 53 which includes a multi-rate adaptive filter 54, a collection and alignment routine 56, and a tail extension processor 58. As shown, input digital audio source samples are digitized by an analog to digital converter (not shown), for example, a 16 bit or 24 bit, PCM, 44.1, 48, 88.2, 96, 176.4 or 192 kHz sample rate, mono or multi channel ADC, such as the stereo ADC within the Cirrus Crystal CS4226 codec, and applied to the runtime input channel processing routine 50, which converts the sample, which are in the time domain to the frequency domain and applies the frequency domain samples to the runtime sequencing, control and data manager 52. In addition, impulse response data representing, for example, the impulse responses corresponding to the characteristics of various audio characteristics, such as, user-selected microphones, musical context(i.e. acoustic space), musical instruments, and relative positioning of the user selected microphones and/or musical instruments within the user selected musical context are stored in a coefficient storage memory device 60. A loadtime coefficient processing routine 62 and a runtime coefficient processing routine 64 are used to successively process coefficients from the coefficient memory storage device 60 based an the user input 66 provided via, for example, a control panel or graphical user interface, such as depicted in FIGS. 1A-1D

In order to reduce runtime CPU resource utilization, the loadtime coefficient processing routine 62 pre-processes at load time the time domain impulse coefficients from storage device 60 with audio signal processing to facilitate changes to the audio response based on user input, and converts the resulting time domain coefficient data into the frequency domain. The runtime sequencing, control, and data manager 52 processes the audio source input samples and the processed impulse response coefficients as to facilitate CPU load balancing and efficient real time processing. The processed samples and coefficients from the runtime sequencing, control, and data manager 52 are applied to the process channel module 53 in order to produce audio output samples 68, which emulate the audio response of the input audio source to various user selected audio characteristics.

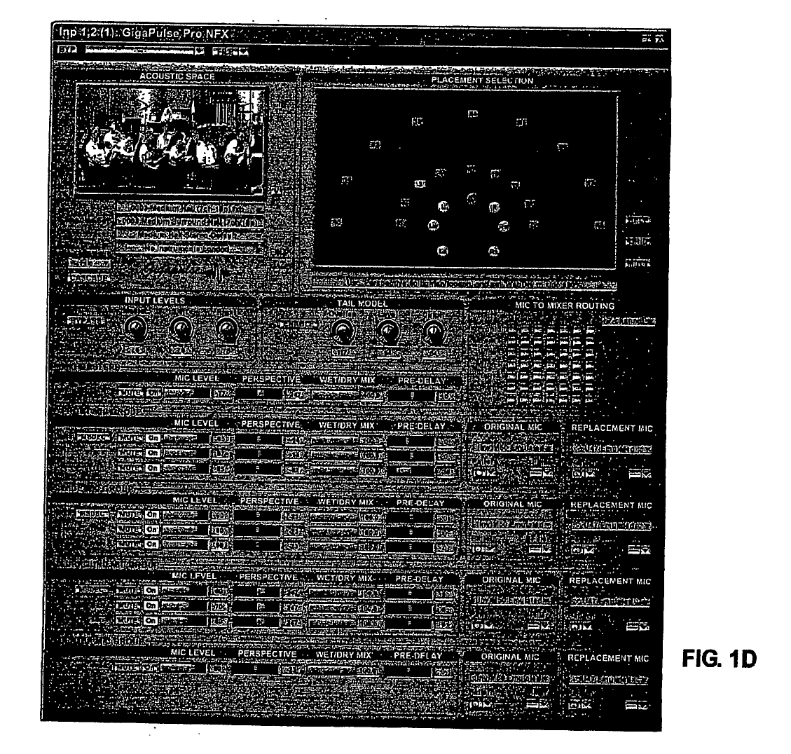

FIG. 3 illustrates a block diagram of one exemplary embodiment of the runtime input channel processing routine 50 shown in FIG. 2. Referring to FIG. 3, the runtime input channel processing routine 50 receives digitized audio source samples at a first sample rate, for example 48 kHz, from a digital sample buffer (IOBUF) 70. The digital sample buffer 70 is sized 32 audio samples of 32 bits each. Digital samples from the digital sample buffer 70 are copied on a frame-by-frame basis by frame copy routines (B) and (A) 72 and 74, respectively, to respective frame buffers (XLB) and (XLA) 76 and 78, respectively. More particularly, the same input samples are framed into two separate buffers, XLB and XLA, of potentially different frame sizes as to facilitate subsequent processing at two different sample rates. The frame size of the XLB buffer is smaller relative to XLA, typically one eighth in size relative to XLB. The tail maintenance routine 80 copies a finite impulse response (FIR) filter length of data from the beginning to the end of the frame buffer XLA, as to cover the FIR coefficient overlap required by the 2:1 decimation filter 90. The decimation filter 90 downsamples the entire XLA frame size of audio source samples, said frame size corresponding to the lower sample rate, for example ½ the audio source sample rate and copies these samples to the decimation frame buffer (Xl_lp) 92.

A fast Fourier transform (FFT) module 82, including FFT routines 84, 86, and 88, is provided for converting frames of data, which are represented in the time domain in frame buffers 76 and 78 into corresponding frequency-domain data. More particularly, the FFT routine 84 produces a fast Fourier transform of an XLB frame from the frame buffer 76 and provides the transformed data to a frequency domain buffer (XLBF) 94. In a turbo mode, frame data from the frame buffer (XLA) 78 is filtered by a low-pass filter, for example a 2:1 filter to reduce the sample rate to ½ of the audio input source sample rate. The low pass filter simply reduces the audio bandwidth to one half of the input sample bandwidth and truncates the result by saving only every other sample. The filtered samples are stored in a decimation frame buffer (Xl-lP) 92. This decimation frame buffer 92 contains the band reduced and truncated samples produced by low pass filtering and throwing away every other sample, and passes these samples to the FFT routine 86 which performs an FFT on the decimated, filtered frame data and stores the resulting frequency domain frame data in a frequency domain buffer (XLAF) 96.

In the event a user wishes not to employ tail end processing (i.e., preferring instead to achieve the acoustic accuracy of full-sample-rate convolution which results greater processing power), the FFT module 88 may be operated at the full sample rate (i.e. same sample rate as the input samples) to transform the frame data from the frame buffer (XLA) 78 at its original sample rate and thus provide full-sample-rate frequency domain data to the frequency domain buffer 96 (XLAF).

Operation of the frame copy routines (B) and (A) 72 and 74, the tail maintenance routine 80, the FFT module 82, and the low-pass alter 90 is handled by a frame control process routine 98. The frame control process routine synchronizes the timing of the frames so that they work in phase together, assembling a frequency domain frame which is larger than the time domain frame size, such that an entire frequency domain frame is made up of multiple time domain frames. The frame control process also synchronizes the multiple sample rates and frame sizes of the XLA, XLB, XLAF, and XLBF buffers, as fed into the real time scheduling and CPU load balancing routines within the runtime sequencing, control and data manager 52.

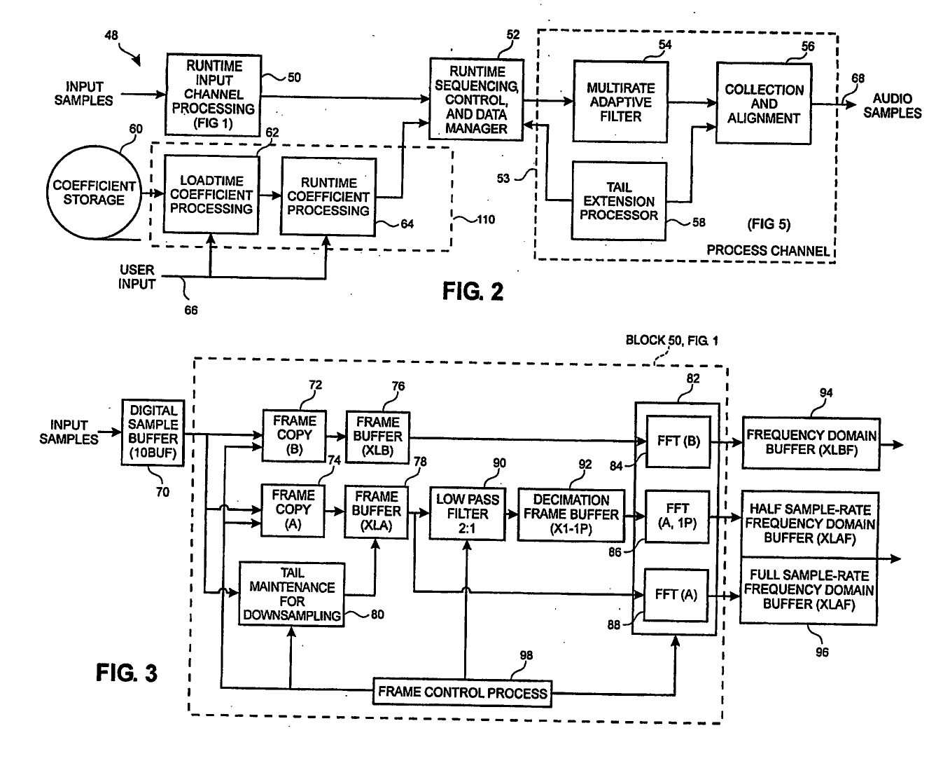

FIG. 4 depicts a block diagram illustrating in greater detail the audio processing system shown in FIG. 2, including an expanded illustration of the flow of data that occurs in operation of that system. As shown, a plurality of audio source input channels are shown, CH. 1, CH. 2. . . . CH. N. As discussed above, the audio source input channels CH. 1, CH. 2. . . . CH. N. are each processed by the runtime input channel processing routine 50 (FIG. 3) which is used to convert the time domain audio source samples, segregated into multiple sample rates, to their respective frequency domain buffers for further processing. As discussed above, the frequency domain samples for each channel are stored in a plurality of frame buffers XLBf1, XLAf2 . . . ; XLAfN, identified with the reference numerals 102, 103 and 104, respectively, one frame buffer for each channel. Each of the frame buffers 102, 103, 104 is sized to receive one frame of input audio samples at a time from a corresponding one of the N audio input channels, for example 2048 32 bit samples. The run time memory 100 also includes a plurality of data structures 106, 107, 108 which represent the coefficients, for example, of M impulse responses for M acoustic characteristics (i.e. acoustical space models or other acoustic characteristics), and their respective control parameters, indices, and buffers. The impulse response data is retrieved from the co-efficient memory storage device 60 by a load and process routine 110 in response to a user command monitored by a load and process routine 110 via an I/O control routine 111. Routine 110 is comprised of routines 62 and 64 (FIG. 2). In particular, the I/O control routine simply monitors user inputs to the GUIs illustrated in FIG. 1A or 1B and retrieves the data structures of the co-efficients that correspond to the user selected acoustic characteristic. The load and process routine 110 simply loads the selected data structures into the flirt-time memory 100 on a channel by channel basis. These data structures are identified in the runtime memory as IMPULSE 1, IMPULSE 2 . . . IMPULSE M, 106, 107 and 108, respectively. As shown in FIG. 4, the frequency domain data PXLBf1, PXLAf1; PXLBf2, PXLAf2; . . . PXLBfN, PXLAfN from the frame buffers 102, 103, 104 and the data structures plc1, plc2 . . . plcM, 106, 107, 108, respectively is communicated to a channel sequencing module 118 which serves to time-multiplex the data for processing by the process 53. Its particular, information passed from the channel sequencing module 118 to the process channel module 120 includes, for each of the N audio input channels, data representing a time synchronized lost framed portion of each frame of data received via that audio input channel (PXLBf(i), i=1, 2, . . . N), data representing a time-synchronized second framed portion of the same data received via that audio input channel (PXLAI(i), i=1, 2, . . . N). Other variables are also passed to the process channel module 53: Plc(i) is a pointer to the tagDynamicChannelData data of impulse channel (i), PIOBuf(i) is a pointer to the output buffer of impulse channel (i), dwFRAMESize is the number of time domain samples input into and output from the process channel routine 53 each time it is called by the host, PI is the pointer to the instance data structure, which is unique to the instance but shared amongst the plurality of channels for each instance, simulated stereo is a control bit which enables/disables the simulated stereo function, M/S decode is a control bit which enables/disables the Mid-Side audio decoder function, and control is a real time scheduling control bit which enables left and right channels to be processed on separate frames to facilitate real time processing CPU load balancing. All of this data passes from the channel sequencing module 118 to the process channel routine 120. As also shown in FIG. 4, bi-directional communication is provided between the process channel routine 53 and the run time memory 100, indicated by arrows 122.

A plurality of T output buffers OUT 1, OUT 2 . . . OUT T, identified with the reference numerals 112, 113, 114, are provided in the run-time memory 100. Each of the output buffers 112, 113 and 114 is sized to receive one frame of output audio samples at a time for outputting the respective T output sample streams. The output buffer pointers pIOBuf1, pIOBuf2 . . . pIOBufT for the user selected audio characteristic of each channel CH1. 1, CH. 2 . . . CH, N of the input audio samples is time multiplexed by the channel sequencing module 118 to provide independent references to process channel 53, which synthesizes audio output streams in real time into the output buffers OUT 1, OUT 2 . . . OUT T, identified with the reference numerals 112, 113 and 114.

Multiple copies or multiple instances of the same audio processing system 48 can be used simultaneously or in time multiplex. The multiple instances allow for simultaneous processing, for example, of different musical instruments. For example, the relative location of each instrument in an orchestra relative to a microphone can be simulated. Since such instruments are played simultaneously, multiple copies or instances of the audio processing system 48 are required in order to synthesize the effects in real time. As such, the channel sequencing module 118 must provide appropriate references of all of the copies or instances to the process channel module 53. As such, an instance data buffer I, identified with the reference numeral 116, is provided in the runtime memory 100 for each instance of the audio processing system 48 being employed.

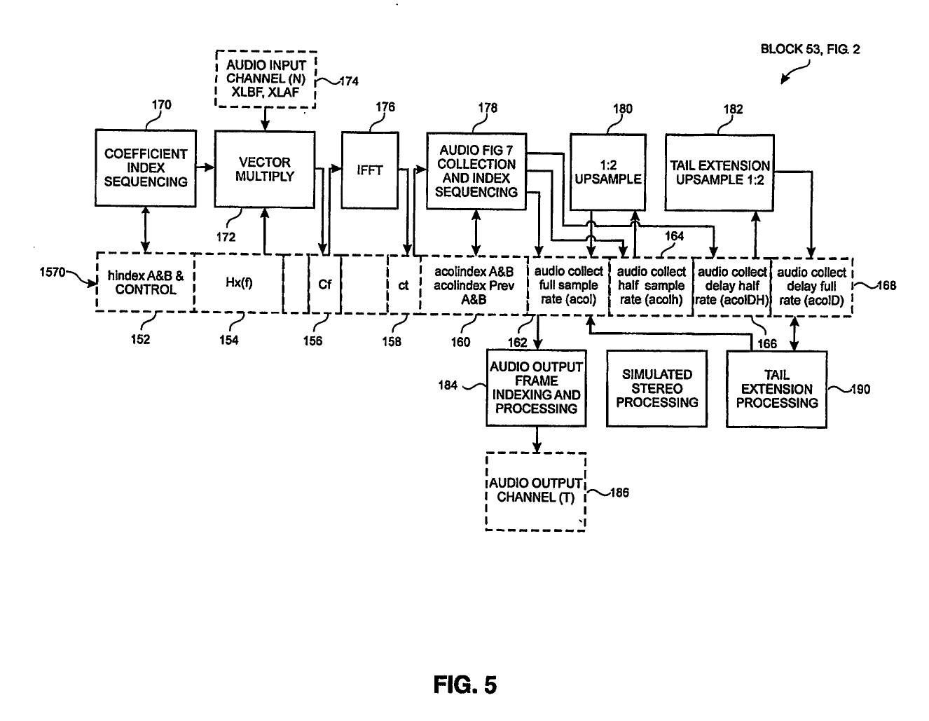

In order to provide a clear understanding of the audio processing involved in the present invention, a time-domain representation of an exemplary impulse response input signal is shown graphically in FIG. 6. As shown, the impulse input signal includes a time wise first portion designated “b”) and a continuous, time wise second portion designated “a”, and a “tail” portion that extends continuously beyond the time wise second portion “a”. In the time domain, the impulse input signal may be partitioned into groups of samples. The first portion of the impulse input signal (herein after referred to as the “b” portion”) preferably includes a number of samples corresponding to the major frame size for FFT blocks XLENA2, and the time wise second portion (herein after referred to as the “a” portion”) preferably is made up of a number of such frames of samples. There is a minor frame size for FFT blocks XLENB2, for example, one eighth of the major block size in the exemplary embodiment. The total number of samples making up the audio signal illustrated in FIG. 6 is denoted by FTAPS2. A pointer hindex is used to designate a relative position within the aggregate collection of samples making up the illustrated audio impulse response or input signal.

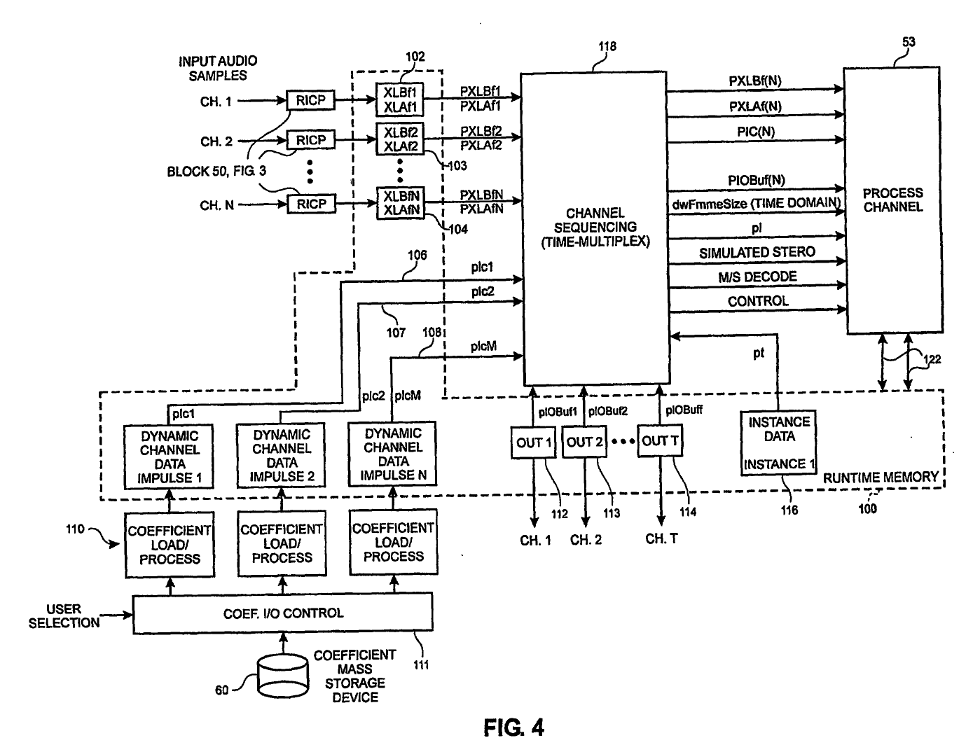

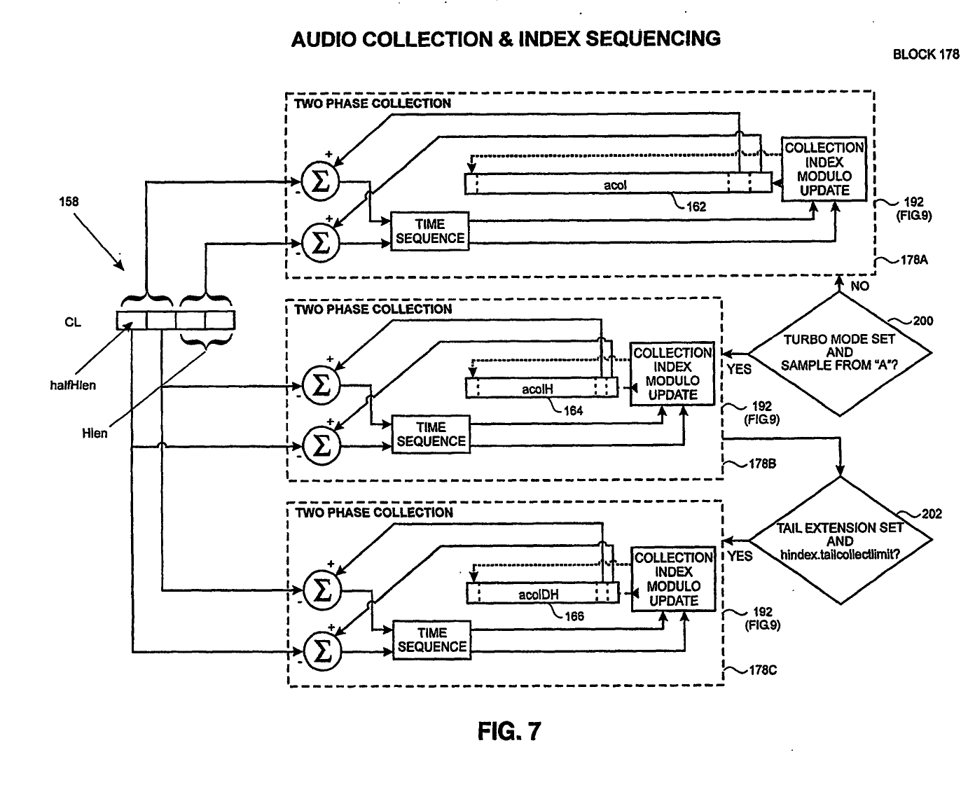

There is a unique co-efficient for the “a” portion and “b” portion, HindexA and HindexB respectively. FIG. 8 illustrates the co-efficient index sequencing routine, illustrated in FIG. 5 by the block 170, and shows the coefficient index sequencing derived from XLENA2, XLENB2, HindexA, HindexB, and HLENAA, the later of which is scaled to half the size of XLENA2 when operating in turbo mode, otherwise is equal to XLENA2. The HindexA and HindexB indices are derived within block 53 and switched by a control signal LPhaseAB to adapt the coefficients within the adaptive filter to accommodate the “a” and “b” portions of the impulse response.

FIG. 5 depicts a block diagram illustrating in greater detail the operation of the process channel routine 53 (FIGS. 2 and 4) as described above, and in particular the pseudo convolution processing routine in accordance with the present invention for use on general purpose CPUs, such as an Intel Pentium 4 processor at a greatly reduced processor load. Conventional frequency domain convolution is simply a vector multiply of frequency domain multiplicands, followed by an inverse Fourier or Fast Fourier transform of the products at a single, uniform, non-time varying, fixed sample rate and block size, resulting in significantly higher computation and throughput. Conventional convolution does not contain the processes necessary for framing, synchronizing or processing the multirate input audio signal, the multirate impulse responses, nor does it employ an adaptive filter with time varying coefficients for a given impulse response.

As shown in FIG. 5, dynamic channel data 150, identified in FIG. 4 as “CONTROL”, from the channel sequencing module 118 is applied to the process channel routine 53. In particular, for each copy or instance of the audio processing system 48, the channel sequencing routine formulates a dynamic data structure 150 for each channel based upon the user selected audio characteristic and the incoming audio source samples. More particularly, as mentioned above, input audio samples are converted to the frequency domain and stored in the runtime memory 100. The impulse response coefficients to the various user selectable acoustic characteristics are likewise stored in the runtime memory 100. All of this data is formulated into a data structure, for example, the exemplary data structure 150, illustrated in FIG. 5. One data structure 150 is provided for each channel of convolution currently being processed in real time and assigned a separate input channel.

The data structure 150 may include at a plurality of exemplary data fields 152, 154, 156, 158, 160, 162, 164, 166, and 168, as shown. As shown in FIG. 5, the frequency domain co-efficients Hx(f) of a finite impulse response (FIR) filter are used to form the field 154. The field 152, accessed via specific reference within the structure pointed to by the lIc(n) pointer identified in FIG. 4, may be used to represent two indexes representing as follows: (1) an index reference (hindex B) representing that a time wise first portion impulse response input data is being processed; (2) an index reference (hindex A) representing that a time wise second portion of the impulse response input data is being processed; and (3) additional control data, such as runtime MicLevel, Perspective, DirectLevel, tail extension audio processing control parameters. Simulated stereo control runtime parameters, and other audio digital signal processing parameters associated with load time or runtime audio processing. These are described further in the tagDynamicChannelData data structure table below.

The field 154 (FIG. 5) contains the frequency domain filter coefficients Hx(f), which may also be in the form of acoustic impulse responses, populated with a frequency domain representation of an acoustic model being simulated in the form of a FIR (e.g., a particular acoustic space, a particular microphone, a particular musical instrument body resonance characteristic, etc.). This finite FIR is stored in the data structure Hx(f), sized to accommodate twice the number of time domain samples making up the acoustic model (i.e., IMPSIZE*2), in order to accommodate the frequency domain representation.

The field 156 is dynamically generated and contains an intermediate part of the product of a vector multiplication from a vector multiplier 172 of the FIR co-efficients panned to by a Co-efficient index Sequencing Routine 170 and the frequency domain audio source input data XLBF, XLAF, illustrated in the box, identified with the reference numeral 174, for the N channels. The buffer XLBF contains the full sample rate, early portion of the impulse response or FIR alter coefficients in the frequency domain output from (FIG. 3) into field 94, and when turbo mode is enabled buffer XLAF contains the half sample rate, later portion of the impulse response or FIR filter coefficients, in the frequency domain output from (FIG. 3) into field 96. The Cf intermediate product is converted to the time domain by the Inverse Fast Fourier Transform routine IFFT 176 and stored in the field 158. The time domain data in field 158, Hlen, halfHlen, is applied to a Audio Collection and Index Sequencing Routine 178 which along with the collection indices data, acolindexA&B, acolindexPrevA&B, in field 160 is used to develop the data in fields 162, 164 and 166, as discussed below.

Hlen represents in the time domain the equivalent of one frame of frequency domain data halfHlen represents in the tune domain the equivalent of one-half frame of frequency domain data.

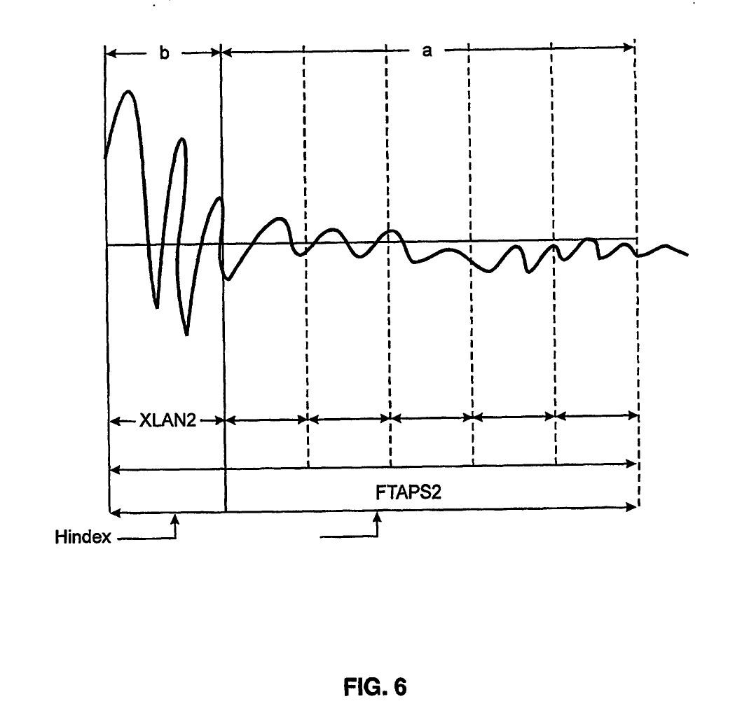

The field 160 contains indices to past and present frames in the audio collection buffer for the B portion of the impulse response (acolindexprevB and acolindexB, respectively, and for the A portion of the impulse response, acolindexprevA and acolindexB, respectively. The field 162 contains the audio collection buffer (acol) 162 corresponding to the processing which occurs at the full sample rate as indicated by the block 178a (FIG. 7), (an intermediate accumulative that facilitates the overlap-add or overlap-subtract) and which comprehends frame-based overlap and modulo addressing. This buffer (acol) 162, is modulo addressed as indicated by the block 192 (FIG. 7) and is sized of length impulse size (the time-domain length of the impulse response) into which successive frames are overlap added or overlap subtracted.

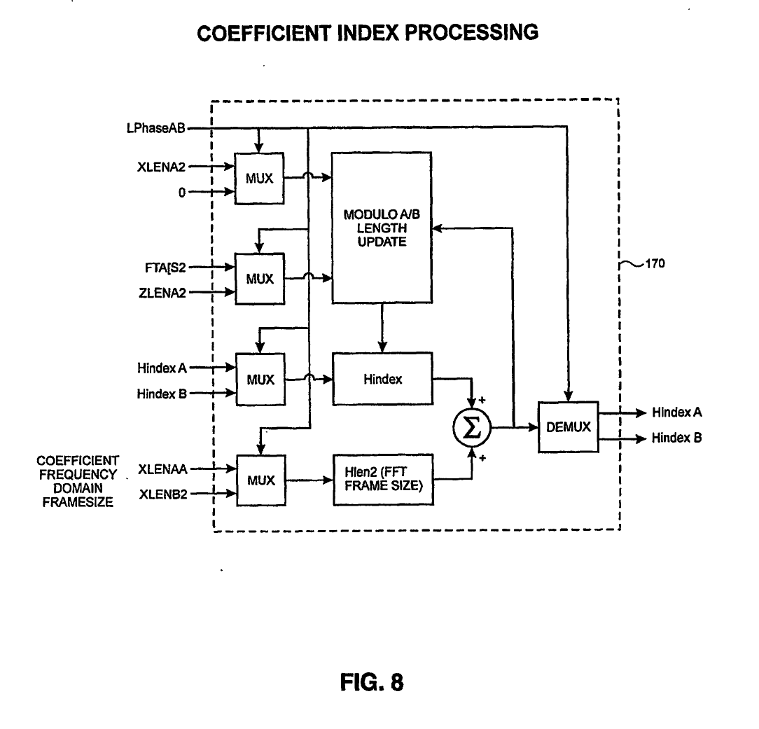

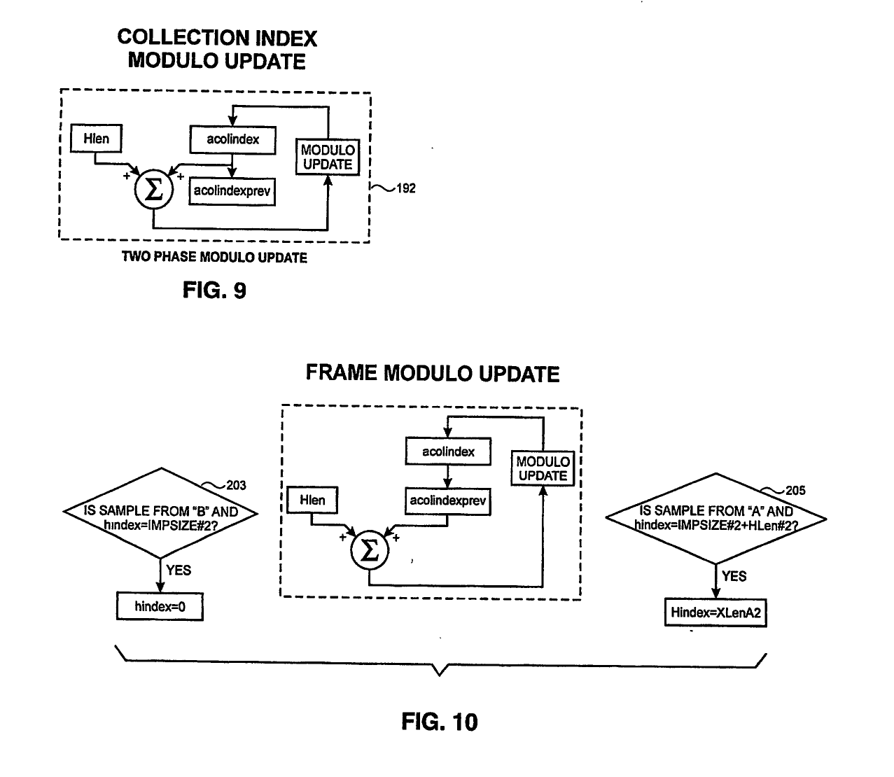

FIG. 9 and FIG. 10 show more detail on the maintenance of the audio collect and hindex indices within the audio collection and index sequencing 178. Prior to a call to the vector multiply 172, Hlen is assigned to either XLenA or XlerB and acolindex is assigned to acolindexA or acolindexB, and the respective impulse coefficient and collection buffer indices are modulo updated. This is done as to adapt the frequency domain filter coefficients on the fly to block processing of multiple portions of an impulse response within the same filter module.

As shown in FIG. 10, the coefficient index hindex, illustrated in FIG. 6, is set depending on which part of the waveform shown in FIG. 6 is being processed. As shown in FIG. 10, if the early part of the waveform is being processed, identified in FIG. 6 as “b”, as determined by the decision block 203, the coefficient index hindex is set to 0. If the later portion of the waveform is being processed, identified in FIG. 6 as “a”, as determined by the decision block 205, the coefficient index is set to XlenA2, which is the beginning of portion “a”.

As shown in (FIG. 7), when the vector multiply and IFFT stages are operating at half of the full sample rate, as when in turbo mode and when processing the sample from portion A as determined by the decision block 200, the audio collection and index sequencing field as generated by the audio collection and index sequencing routine 178 (FIG. 5) and respective collection indices will phase align and overlap-add respective audio frames from the ct field 158 into the buffer(acolh), audio collect half sample rate field 164. Also shown in (FIG. 7), when tail extension is selected and set and the coefficient index, hindex, is greater than the tail collection limit,as determined by the decision block 178b, then the audio collection and index sequencing routine operates as illustrated by the block 178c and the audio collection and index sequencing field 178 (FIG. 5) and the respective collection indices will phase align and overlap-add or overlap-subtract respective audio frames from the ct field 158 into the buffer, acolDH, audio collect delay half rate field 166. The acolh and acolDH buffers, 164 and 166, respectively, are modulo addressed as indicated by the blocks 192 (FIG. 7) and are sized to have a length that is half the impulse size plus the number of taps in the 1:2 upsample filter field 180, the tap length being added to the buffer size in order to facilitate buffer tail overlap typical of FIR type filters.

After all half sample rate processing is offset according to appropriate phase by collection indices and overlap added into acolh, the 1:2 upsample block field 180 converts the half sample rate data into the full sample rate and accumulates the result into the audio collect full sample rate buffer field 162.

After all half sample rate tail extension processing is offset according to appropriate phase by collection indices and overlap added into acolDH, the tail extension 1:2 upsample block field 182 converts this tail extension half sample rate data into the full sample rate and accumulates the result into the tail extension audio collect delay full rate buffer, acoID, field 168.

Tail extension processing is optionally enabled by the user in order to model the very end portion of an impulse response to mitigate the fact that convolution processing is very CPUintensive. More particularly, rather than spend valuable computation time on portions of an impulse response that may be nearing the point of inaudibility or otherwise less significant than earlier portions of an impulse response, tail extension modeling employs an algorithmic model at a far lower computational load. For example, if an impulse response is 4 seconds in duration, the last second may be modeled to save premium convolution processing time for only the early part of the response.

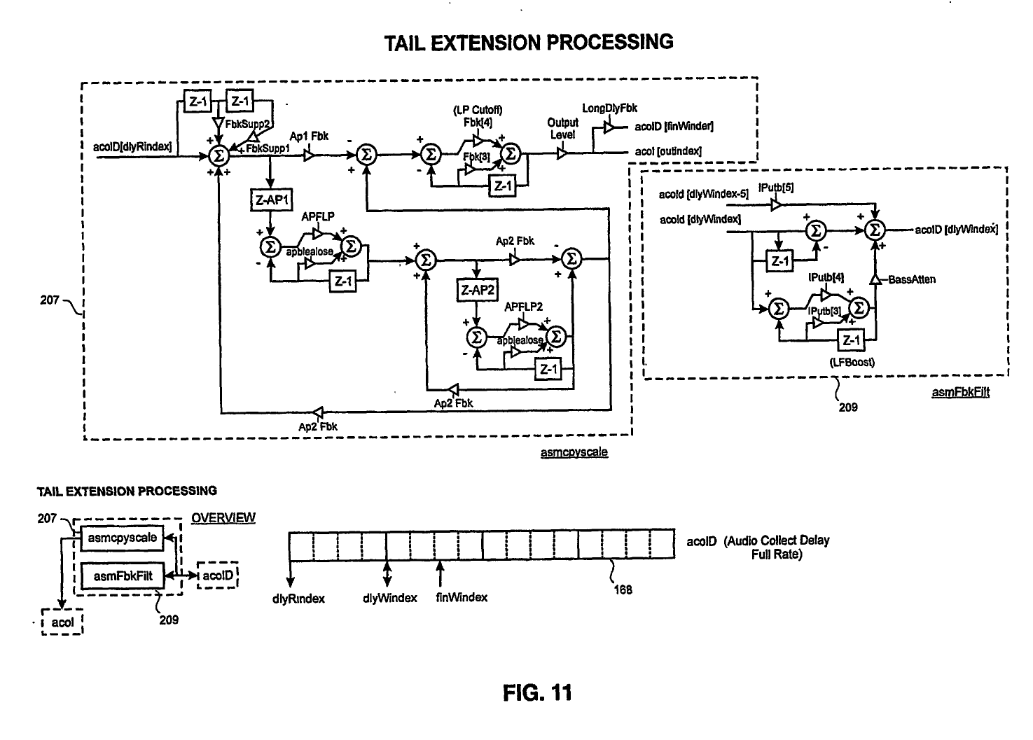

FIG. 11 is an exemplary tail extension model. The model illustrated in FIG. 11 is exemplary and includes a two basic routines; a copy scale routine asmcpyscale 207 and a Alter routine asmfbkfilt.209, as shown. Other configurations are also within the scope of the invention. The audio data written into a read/write buffer acolD 168. As shown in FIG. 5, the tail extension processing routine, processes this data in the buffer acolD and returns it to the buffer acol as shown in FIG. 5.

The later portion of the convolution processing, for example the third second in our 4 second impulse example, may be copied into a buffer, acolDH, at the half sample rate, or acolD at the full sample rate. The tail extension model, similar to a conventional reverberation algorithm, is synchronized and applied to the late response. There are low pass filters for timbre matching, volume control for volume matching to the tail level of the actual impulse, feedback and overlap parameters, all of which facilitate a smooth transition from convolution processing to algorithm processing.

An important aspect of the invention relates to embedding and controlling convolution technology within a sampler or synthesizer that is a music sampler for a music synthesizer engine and what this technology will do is add to the description of a virtual musical instrument. One example relates to modeling an acoustic piano. In that example, the behavior of the piano soundboard resonate is emulated. In this example, the parameters that control the impulse response of the piano soundboard may be saved into a file description which contains both the original samples of the individual notes on the piano and control parameters to dynamically scale the convolution perimeters in real-time such that the behavior of an acoustic piano soundboard is the same as the model version. So, in essence, the system embeds and controls convolution-related parameters within a synthesizer engine-thus embedding that convolution process inside the virtual musical instrument processing itself. Typically, a sampler or synthesizer engine includes an interpolator which gives you pitch control, a low-frequency oscillator or LFO, and all envelope generator. Envelope generators provides dynamic control of amplitude over time which are all processing audio which is routed through a convolution process where now other aspects of the control and modeling of the sound is coming from the synthesizer engine in dynamically controlling the convolution process. Examples of dynamically controlling the convolution process are, controlling the pre and post convolution level control, damping of audio energy from within the convolution buffers for simulating a damping of a piano soundboard as when the damper pedal is raised, changing the wet/dry, adding and subtracting various impulse responses representing various attributes of a sound, and changing the “perspective control”. In regards to “perspective control,” what that is doing is changing the envelope of the impulse response in real-time as a musical instrument is being played. By combining all of these processes, physical instruments can be modeled with far greater detail and accuracy than before.

Various file structures can be employed in which the impulse responses associated with the sound of a musical instrument, the control parameters associated with the impulse responses, the digital sound samples representing single or multiple notes of an instrument, control parameters for the synthesizer engine filters, LFO, envelope generators, interpolators, and sound generators are stored together into a file structure representation of a musical instrument. This file structure has single or multiple data fields representing each of these characters of the synthesized sound, which may be organized in a variety of ways using a variety of file data types. This musical instrument file structure may include the ambient environment, instrument body resonance, microphone type, microphone placement, or other audio character of the synthesized sound. An example file structure is as follows: Impulse Response 1 . . . Impulse Response(n), Impulse Response 1 impulse control 1 . . . Impulse Response 1 impulse control(m), Impulse Response(n) impulse control 1 . . . Impulse Response(n) impulse control(m), digital sound sample 1 . . . digital sound sample(p), sampler engine control parameter 1 . . . sampler engine control parameter (q), synthesizer engine control parameter 1 . . . synthesizer engine control parameter (r), pointer to other file 1, . . . pointer to other file(n). Together, these parameters represent the sound behavior of a musical instrument or sound texture generator, in which the impulse responses and their interactivity within the synthesizer engine via user performance data are contributing to the sound produced by the instrument model.]

An exemplary channel data structure is illustrated below. The Channel Sequencing Routine 118 (FIG. 4) chooses the particular pointers and controls that are fed into process channel[Jim-we need to provide better definition here]. Each instance of this data structure represents one dynamic channel data impulse block in Runtime Memory 100. Piecewise Convolution is done (in portions which are combined) by an “overlap-add” method (technically, overlap-subtract with a downstream phase reversal).

typedef struct _tagDynamicChannelData
{

| DataType | Variable/Field | Description |
|---|---|---|
| Ipp32f | Hx[IMPSIZE*2]; | //filter impulse response (FIR Filter), (Frq domain |
| 32-bit flo [symbol] | | representation of the acoustic model being simulated (e.g., |
| point | | acoustic space, microphone, musical instrument body |
| | | resonance)) |
| Ipp32f | acol[ACOLLENGTH]; | //audio collect (intermediate accumulator for overlap- |
| | | add)-comprehends frame-based overlap and modulo addressing |
| | | modulo addressed buffer sized of length impulse size (the |
| | | time-domain length of the impulse response) into which |
| | | successive frames are overlap added |
| Ipp32f | acolH[(ACOLLENGTH/2) + | //turbo collect, Half size for reduced sample-rate to save |
| | LPFTAPS]; | CPU overhead |
| Ipp32f | acolDH[(ACOLLENGTH/2) + | //turbo tail ext Delay collect, Half size for reduced sample- |
| | LPFTAPS]; | rate to save CPU overhead |
| Ipp32f | acolD[ACOLLENGTH]; | //tail extension delay |
| Ipp32f | tarMicLevel; | //target mic level scale (new setpoint) |
| Ipp32f | delMicLevel; | //delta mic level scale (recursively calculated transition |
| | | level gradulated from one sample to the next to smooth the |
| | | transition) |
| Ipp32f | runMicLevel; | //runtime mic level scale (original being applied) |
| Ipp32f | runMicPerspec; | //runtime mic perspective scale (affects the envelope of the |
| | | impulse response-used for runtime scaling) applies a |
| | | volume scaling to early part of response that increases or |
| | | decreases volume to create perception of a close or distant |
| | | perspective on the audio-correlated to some scape value |
| | | that makes sense for the user interface of the apparent |
| | | distance of the sound source from the mic. |
| Ipp32f | tarDirectLevel; | //target Direct Sim stereo level scale |
| Ipp32f | delDirectLevel; | //delta Direct Sim stereo level scale |
| Ipp32f | runDirectLevel; | //runtime Direct Sim stereo level scale |
| Ipp32f | alignDirect; | //alignment dummy |
| DWORD | hindexA; | //sub frame frq H[hindex] - index reference into impulse |
| unsigned | | response (the current potion on which a calculation is being |
| integer | | performed (A portion, which may be at a lower sample |
| | | rate) |
| DWORD | acolindexA; | //audio collect buffer index - current index into collect |
| | | buffers used for overlap-add |
| DWORD | acolindexprevA; | //previous frame collection buffer index - previous index |
| | | value in the collection or accumulation |
| DWORD | outindex; | //collect buffer output index - index to where data can be |
| | | read from audio collect buffer (second from top above) and |
| | | sent to output buffer |
| DWORD | hindexB; | //sub frame frq H[hindex] |
| DWORD | acolindexB; | //audio collect buffer index |
| DWORD | acolindexprevB; | //previous frame collection buffer index |
| DWORD | dummyxxxx; | //alignment dummy (placeholder) |
| DWORD | dlyWindex; | //tail extension delay Write index (delay needed to align |
| | | modeled portion of the impulse response with the actual |
| | | result of the impulse response) |
| DWORD | dlyRindex; | //tail extension delay Read index (delay needed to align |
| | | modeled portion of the impulse response with the actual |
| | | result of the impulse response) |
| DWORD | te1A; | //tail extension state variable (for Tail Extension Filter) |
| DWORD | te2A; | //tail extension state variable |
| DWORD | FcFbk; | //tail extension state variable |
| DWORD | FcFbk2; | //tail extension state variable |
| DWORD | FcFbk3; | //tail extension state variable |
| DWORD | FcFbk4; | //tail extension state variable |
| DWORD | FcFbk5; | //tail extension state variable |
| DWORD | FcFbk6; | //tail extension state variable |
| DWORD | alignte1; | //16 byte alignment dummy |
| DWORD | alignte2; | //16 byte alignment dummy |
| Ipp32f | AP1[ALL_PASS_SAMPLES]; | //tail extension, all-pass buffer |
| Ipp32f | AP2[ALL_PASS_SAMPLES]; | //tail extension, all-pass buffer |
| Ipp32f | SSt[SIM_STEREO_SAMPLES] | //sim stereo delay buffer (for slow processors; simulates |
| | | stereo audio by using stereo audio filters and |
| | | complementary comb filters. OPTIONAL |
| Ipp32f | SStDD[SIM_STEREO_SAMPL [symbol] | //sim stereo, direct delay buffer |
| DWORD | AP1_r; | //AP buffer read index |
| DWORD | AP2_r; | //AP buffer read index |
| DWORD | SSt_r; | //Sim Stereo buffer read index |
| DWORD | AP1_w; | //AP buffer write index offset |
| DWORD | AP2_w; | //AP buffer write index offset |
| DWORD | tarSSt_w; | //target Sim Stereo buffer write index offset |
| Ipp32f | tarSStWidth; | //target Sim stereo depth |
| Ipp32f | delSStWidth; | //delta Sim stereo depth |
| Ipp32f | runSStWidth; | //runtime Sim stereo depth |
| DWORD | delSSt_w; | //delta Sim Stereo buffer write index offset |
| DWORD | runSSt_w; | //runtime Sim Stereo buffer write index offset |
| DWORD | SStDD_w; | //sim stereo, direct delay write offset |

} DYNAMICCHANNELDATA, *PDYNAMICCHANNELDATA; [symbol]
indicates data missing or illegible when filed

The foregoing description is for the purpose of teaching those skilled in the art the best mode of carrying out the invention and is to be construed as illustrative only. Numerous modifications and alternative embodiments of the invention will be apparent to those skilled in the art in view of this description, and the details of the disclosed structure may be varied substantially without departing from the spirit of the invention. Accordingly, the exclusive use of all modifications within the scope of the appended claims is reserved.

What is claimed and desired to be covered by a Letters Patent follows:

1. A synthesizer, comprising:
means for receiving an input audio stream representing an audio performance and including a plurality of audio input samples at a first sample rate;
means for receiving data representing an impulse response that corresponds to an acoustic effect; and
means for generating an output audio stream during a response time based on the input audio stream and the impulse response by convolving the audio input samples with the data representing the impulse response for a portion of the response time and modeling an output audio system during the balance of the response time.

2. The synthesizer of claim 1, further comprising means for receiving from a user an indication of the acoustic effect.

3. The synthesizer of claim 1, wherein the acoustic effect comprises an acoustic modification of the audio performance.

4. The synthesizer of claim 1, wherein the input audio stream comprises a plurality of audio input samples for each of a plurality of input channels.

5. The synthesizer of claim 1, wherein the output audio stream includes a plurality of output channels.

6. The synthesizer of claim 1, wherein the acoustic effect comprises acoustically simulating recording the audio performance using a particular microphone.

7. The synthesizer of claim 1, wherein the acoustic effect comprises acoustically simulating recording the audio performance using a particular microphone placement.

8. The synthesizer of claim 1, wherein the acoustic effect comprises acoustically simulating recording the audio performance in a particular musical context.

9. The synthesizer of claim 1, wherein the acoustic effect comprises acoustically simulating playing at least a portion of the audio performance using a particular instrument body.

10. The synthesizer of claim 1, wherein the acoustic effect comprises acoustically simulating playing at least a portion of the audio performance using a particular instrument placement.

11. The synthesizer of claim 1, wherein the generating means comprises means for recursively extrapolating a tail portion of the output audio stream.

12. The synthesizer of claim 1, wherein the audio performance includes a first number of source channels, and wherein the output audio stream generated by the generating means includes a second number of output channels greater than the first number of source channels.

13. The synthesizer of claim 12, wherein the audio performance includes only a single source channel and wherein the output audio stream comprises a simulated stereo version of the single source channel.

14. An acoustic synthesizer for synthesizing one or more acoustic effects, the acoustic synthesizer comprising:
an input subsystem for receiving an input audio stream and storing said input audio stream in a predetermined file structure; and
an acoustic synthesizer subsystem for emulating an acoustic effect and generating an output audio stream as a function of said input audio stream and said acoustic effect defined by one or more acoustic parameters, said acoustic parameters stored in said predetermined file structure.

15. The acoustic synthesizer as recited in claim 14, wherein said acoustic synthesizer subsystem includes a system for varying the acoustic effect and resulting output audio stream in real time.

16. The acoustic synthesizer as recited in claim 14, wherein said predetermined file structure includes a plurality of data fields.

17. The acoustic synthesizer as recited in claim 16, wherein said plurality of data fields define a plurality of data types.

18. The acoustic synthesizer as recited in claim 17, wherein at least one of said data types includes ambient environment data.

19. The acoustic synthesizer as recited in claim 16, wherein said plurality of data fields define an instrument.

20. The acoustic synthesizer as recited in claim 16, wherein said plurality of data fields define a microphone type.

21. The acoustic synthesizer as recited in claim 16, wherein said plurality of data fields define a document.
